(19) United States
(12) Patent Application Publication
(10) Pub. No.: US 2024/0219242 A1
(43) Pub. Date: Jul. 4, 2024

(54) JIG FOR MEASURING TEMPERATURE AND HUMIDITY OF RETICLE CARRIER

(71) Applicant: GUDENG EQUIPMENT CO., LTD., New Taipei City (TW)

(72) Inventors: CHAO-CHIN CHIN, New Taipei City (TW); KENG-LIANG LIN, New Taipei City (TW); CHIN-HUNG WEN, New Taipei City (TW); AN-PANG WANG, New Taipei City (TW)

(21) Appl. No.: 18/091,398

(22) Filed: Dec. 30, 2022

(51) Int. Cl. G01K 1/024; G01F 15/061; G03F 7/20

(52) U.S. Cl. CPC G01K 1/024; G01F 15/061; G03F 7/7085; G03F 7/70891

(57) ABSTRACT

A jig for measuring temperature and humidity of a reticle carrier comprises: a jig body, a detection module, a wireless communication module and a capacitor, the jig body has a storage space, at least one air inlet hole and at least one air outlet hole communicated to the storage space; the detection module includes a thermometer and a hygrometer, the thermometer and the hygrometer are disposed in the storage space; the wireless communication module is connected to the thermometer and the hygrometer by signal; the capacitor is electrically connected to the detection module and the wireless communication module. The jig for measuring temperature and humidity of the reticle carrier of the present disclosure is used to keep tabs on the temperature and humidity and the changes inside the reticle carrier.

### BACKGROUND OF THE INVENTION

### 1. Field of the Invention

The present application relates to a jig for detecting temperature and humidity, and in particular to a jig for measuring temperature and humidity of a reticle carrier.

### 2. Description of the Related Art

In the advanced lithography process in the semiconductor field, especially the extreme ultraviolet light (EUV) lithography process, the requirement for cleanliness of the process environment is extremely high. If particles contaminate the reticle, it will cause defects in the photographic process. In order to achieve the requirements for cleanliness and protecting the reticle, a reticle carrier is generally used to block the external particles. In order to keep the reticle carrier itself dry, the general practice is to introduce dry gas (compressed dry gas or nitrogen) into the reticle carrier.

However, when filling the gas, it is necessary to know the temperature and humidity and the changes inside the reticle carrier at this time, in order to accurately keep tabs on the state inside the reticle carrier in real time.

### BRIEF SUMMARY OF THE INVENTION

Therefore, in order to solve the various problems of the reticle carrier, the disclosure provides a jig for measuring temperature and humidity of a reticle carrier.

To achieve the above objective and other objectives, the present disclosure provides a jig for measuring temperature and humidity of a reticle carrier, which comprises: a jig body, having a storage space, at least one air inlet hole and at least one air outlet hole communicated to the storage space; a detection module, including a thermometer and a hygrometer, the thermometer and the hygrometer are disposed in the storage space; a wireless communication module, connected to the thermometer and the hygrometer by signal; and a capacitor, electrically connected to the detection module and the wireless communication module.

In an embodiment of the present disclosure, the detection module further comprises a flowmeter and a display, the flowmeter is disposed in the storage space, and is connected to the display by signal.

In an embodiment of the present disclosure, the detection module further comprises a starting switch, connected to the thermometer and the hygrometer by signal.

In an embodiment of the present disclosure, the wireless communication module is a Bluetooth communication module.

In an embodiment of the present disclosure, the jig body is provided with a wired charging interface.

In an embodiment of the present disclosure, a top of the jig body is provided with a handle.

In an embodiment of the present disclosure, the jig further comprises a counterweight block, disposed in the storage space.

Accordingly, the jig for measuring temperature and humidity of the reticle carrier of the present disclosure can accurately measure the temperature and humidity changes inside the reticle carrier by the detection module when dry gas is poured into the reticle carrier, and transmit and record the value by the wireless communication module and other elements, can regularly check the gas supply source and record the data to learn the state of gas supply source, and then judge and analyze and prevent in advance, thereby reducing the possibility of abnormal temperature and humidity inside the reticle carrier, and decreasing the risk of deterioration and damage of the reticle carrier or reticle.

### BRIEF DESCRIPTION OF THE DRAWINGS

FIG. 1 is a schematic perspective view of a jig for measuring temperature and humidity of a reticle carrier according to an embodiment of the present disclosure.

FIG. 2 is a schematic sectional view of the jig for measuring temperature and humidity of the reticle carrier according to the embodiment of the present disclosure.

FIG. 3 is a schematic block diagram of the jig for measuring temperature and humidity of the reticle carrier according to the embodiment of the present disclosure.

### DETAILED DESCRIPTION OF THE INVENTION

To facilitate understanding of the present application, embodiments together with the attached drawings for the detailed description of the present application are provided. One skilled in the art can understand the object, characteristics and effects of this present application by the content described in the specification. It should be noted that various possible modifications and alterations to the details of the specification could be carried out by implementing or applying other different embodiments based on different views and applications without departing from the spirit of the present application. The related technical contents of the application will be described in detail by the embodiments. However, the disclosed contents should not be considered to limit the scope of the application. The description is provided as follows:

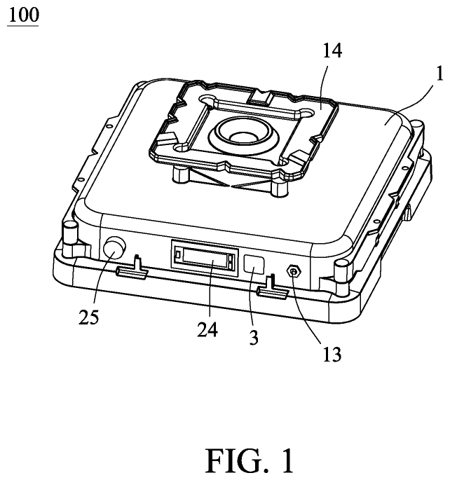

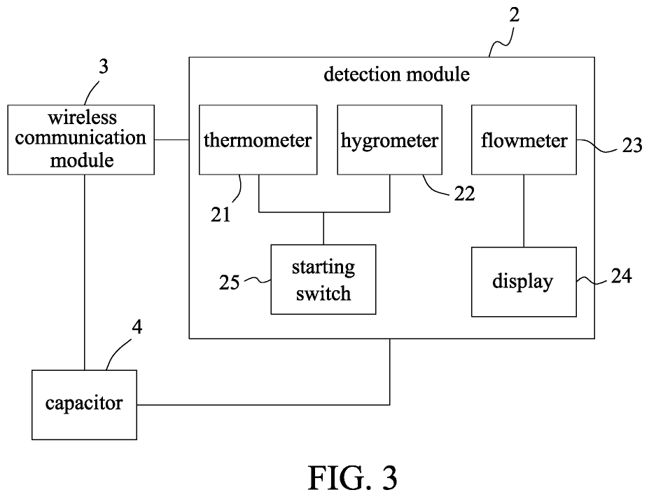

As shown in FIGS. 1 to 3, a jig 100 for measuring temperature and humidity of a reticle carrier of an embodiment of the present disclosure comprises: a jig body 1, a detection module 2, a wireless communication module 3 and a capacitor 4.

The jig body 1 has a storage space S, at least one air inlet hole 11 and at least one air outlet hole 12 communicated to the storage space S, the present embodiment has two air inlet holes 11 and two air outlet holes 12. These air inlet holes 11 and air outlet holes 12 penetrate a bottom face of the jig body 1. The specific shape of the jig body 1 may be according to the shape of the reticle carrier, in this embodiment, the jig body 1 is roughly a rectangular box, and a top of the jig body 1 is provided with a handle 14, which is convenient to move the jig body 1 in a grasping manner.

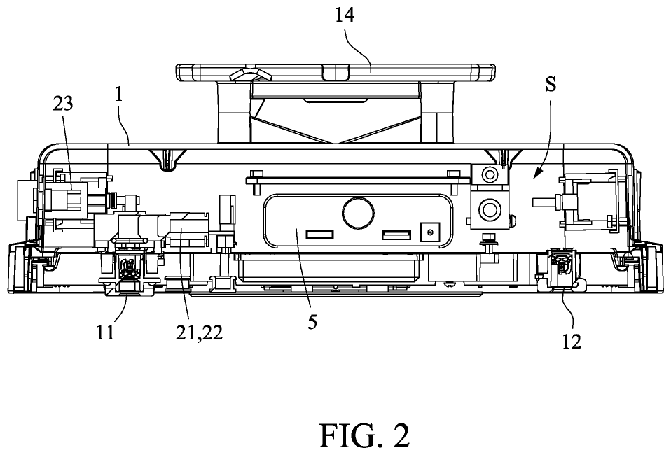

The detection module 2 includes a thermometer 21 and a hygrometer 22, the thermometer 21 and the hygrometer 22 are disposed in the storage space S. The thermometer 21, for example, is a thermistor thermometer, thermocouple thermometer, infrared thermometer and other conventional temperature measurement devices; the hygrometer 22, for example, is a capacitive hygrometer, resistive hygrometer, thermally conductive type hygrometer and other conventional humidity measurement devices, and the present disclosure is not limited to thereto. The thermometer 21 and the hygrometer 22 may also be combined into a thermohydrometer (as shown in FIG. 2), or may also be divided into two members.

The wireless communication module 3 is connected to the thermometer 21 and the hygrometer 22 by signal. The wireless communication module 3 receives the temperature and humidity information measured by the thermometer 21 and the hygrometer 22 and transmits it to an external mechanism. The wireless communication module 3, for example, is a Bluetooth communication module, which transmits temperature and humidity information to remote computers, mobile phones and other terminal devices by means of Bluetooth wireless transmission.

The capacitor 4 is electrically connected to the detection module 2 and the wireless communication module 3 to supply power required by the detection module 2 and the wireless communication module 3. The capacitor 4, for example, is a rechargeable battery. The wireless communication module 3 may also transmit power information of the capacitor 4 to the external mechanism.

In summary, by the jig 100 for measuring temperature and humidity of the reticle carrier of the present disclosure, it can accurately measure the temperature and humidity changes inside the reticle carrier by the detection module 2 when dry gas is poured into the reticle carrier, and transmit and record the value by the wireless communication module 3 and other elements, can regularly check the gas supply source and record the data to learn the state of gas supply source, and then judge and analyze and prevent in advance, thereby reducing the possibility of abnormal temperature and humidity inside the reticle carrier, and decreasing the risk of deterioration and damage of the reticle carrier or reticle.

Further, in the present embodiment, as shown in FIG. 2, the detection module 2 further comprises a flowmeter 23 and a display 24, the flowmeter 23 is disposed in the storage space S, and is connected to the display 24 by signal. The flowmeter 23, for example, is a flow sensor for measuring liquid, gas and other fluids, such as thermal mass flowmeter, diaphragm flowmeter or ultrasonic flowmeter, and the present disclosure is not limited to thereto. The display 24, for example, is a liquid crystal display, preferably disposed on an outer surface of the jig body 1. The display 24 receives the flow signal measured by the flowmeter 23 and displays it.

Further, in the present embodiment, as shown in FIG. 1, the detection module 2 further comprises a starting switch 25, connected to the thermometer 21 and the hygrometer 22 by signal. The starting switch 25 may be a mechanical trigger switch to turn on/off the thermometer 21 and the hygrometer 22, or may be electrical or other types of switches. The starting switch 25 may also be further linked to the display 24 to turn on/off the display 24.

Further, in the present embodiment, as shown in FIG. 1, the jig body 1 is further provided with a wired charging interface 13, the wired charging interface 13 for example, is a universal serial bus (USB) interface, or a conventional wired power transmission interface. The capacitor 4 may be connected to a charging source in a wired manner via the wired charging interface 13 as an auxiliary charging method.

Further, in the present embodiment, as shown in FIG. 2, the jig 100 for measuring temperature and humidity of the reticle carrier of the present disclosure further comprises a counterweight block 5, disposed in the storage space S. The counterweight block 5 may balance a load of the jig body 1, and simulates the weight at the reticle carrier carrying the reticle.

While the present application has been described by means of specific embodiments, those skilled in the art should understand the above description is merely embodiments of the application, and it should not be considered to limit the scope of the application. It should be noted that all changes and substitutions which come within the meaning and range of equivalency of the embodiments are intended to be embraced in the scope of the application. Therefore, the scope of the application is defined by the claims.

What is claimed is:

1. A jig for measuring temperature and humidity of a reticle carrier, comprising:
a jig body, having a storage space, at least one air inlet hole and at least one air outlet hole communicated to the storage space;
a detection module, including a thermometer and a hygrometer, the thermometer and the hygrometer are disposed in the storage space;
a wireless communication module, connected to the thermometer and the hygrometer by signal; and
a capacitor, electrically connected to the detection module and the wireless communication module.

2. The jig for measuring temperature and humidity of the reticle carrier according to claim 1, wherein the detection module further comprises a flowmeter and a display, the flowmeter is disposed in the storage space, and is connected to the display by signal.

3. The jig for measuring temperature and humidity of the reticle carrier according to claim 1, wherein the detection module further comprises a starting switch, connected to the thermometer and the hygrometer by signal.

4. The jig for measuring temperature and humidity of the reticle carrier according to claim 1, wherein the wireless communication module is a Bluetooth communication module.

5. The jig for measuring temperature and humidity of the reticle carrier according to claim 1, wherein the jig body is provided with a wired charging interface.

6. The jig for measuring temperature and humidity of the reticle carrier according to claim 1, wherein a top of the jig body is provided with a handle.

7. The jig for measuring temperature and humidity of the reticle carrier according to claim 1, further comprising a counterweight block, disposed in the storage space.
